(19) United States
(12) Patent Application Publication
(10) Pub. No.: US 2010/0012170 A1
(43) Pub. Date: Jan. 21, 2010

(54) High Efficiency Solar Cell

(76) Inventors: Argyrios C. Varonides, Scranton, PA (US); Robert A. Spalletta, Scranton, PA (US)

Correspondence Address: Charles L. Riddle, Esq., 434 Lackawanna Ave, Suite 200, Scranton, PA, 19465, US

(21) Appl. No.: 12/505,621

(22) Filed: Jul. 20, 2009

Related U.S. Application Data
(60) Provisional application No. 61/082,222, filed on Jul. 20, 2008.

(51) Int. Cl. H01L 31/052; H01L 31/00

(52) U.S. Cl. 136/246; 136/255; 136/256

(57) ABSTRACT

The present invention is a high-efficiency solar cell having a top cell [1300] optimized to absorb incident radiant energy in a first absorption band and a bottom cell [1500] attached to the top cell optimized to absorb incident energy in a second absorption band which preferably does not substantially overlap the first absorption band. The top cell [1300] employs a first layer [1310] being a highly doped n-type material, a second layer [1330] being a lightly doped n-type material in contact with the first layer [1310], and a p-type material [1350] in contact with the second layer [1330] optimized to pass the lower frequencies of incident radiation to the bottom cell [1500]. The bottom cell [1500] has a quantum cell region [1550] comprised of a plurality of quantum wells. The quantum wells are designed to absorb near 1 eV. Alternatively, the incident radiant energy may be diffracted into frequency bands with each solar cell tuned to absorb one specific band.

### CROSS REFERENCE TO RELATED APPLICATIONS

This application claims priority to U.S. Provisional Application Ser. No. 61/082,222 filed on Jul. 20, 2008, and incorporates the application by reference in its entirety as if specifically set forth herein.

### FEDERAL SPONSORED RESEARCH

Not Applicable

### SEQUENCE LISTING OR PROGRAM

Not Applicable

### BACKGROUND OF THE INVENTION

1. Field of the Invention

This invention relates to an improved solar cell for converting light into electricity.

2. Discussion of Prior Art

Due to global warming and the rising cost of energy, there is a renewed interest in the use of solar cells. Solar cells are devices that convert sunlight to electricity. Incident light photons strike the surface of the solar cell and excite carriers in molecules of the solar cell material causing them to jump quantum states from the valence band to the conduction band. This frees the electrons allowing them to move freely. The free moving electrons are electrical currents. The field of converting light energy to electricity is better known as photovoltaics.

Silicon has been the prime material for most of photovoltaic applications. Commercially available silicon solar cells convert sunlight to electricity at collection efficiency levels that vary from 10 to 15%. This is a low percentage of power conversion, and given the overall cost, not an efficient energy source. There have been some advances with other materials, but they still suffer from low efficiency.

Each photovoltaic material converts only a portion of sunlight into electricity, in other words, only a range of incident wavelengths can be absorbed by a specific medium. The rest of the photons in different frequency bands remain un-absorbed and therefore lost. Therefore, every solar cell would be limited by the materials used.

There have been attempts to convert a larger percentage of the incident light frequency band, however, there have been problems creating cells with the proper absorption bands.

Currently there is need for a solar cell which more efficiently converts light energy into electricity.

### OBJECTS OF THE INVENTION

It is an object of the present invention to more efficiently convert light energy into electricity.

It is another object of the present invention to provide a cost-effective electric energy creation device.

It is another object of the present invention to provide a device for creating electricity from light which requires less light for the same amount of electricity as compared with the prior art.

It is another object of the present invention to provide a device which converts a greater percentage of a light emission spectrum into electricity.

### SUMMARY OF THE INVENTION

The present invention may be embodied as a high-efficiency solar cell comprising:

a) a top cell 1300 optimized to absorb incident energy in a first absorption spectrum having:
i. a first layer 1330 being a highly doped n-type material aluminum arsenide (AlAs) doped at 10¹⁹ n-type particles/cm³ being 90 nm thick,
ii. a second layer 1350 being a lightly doped n-type material, such as aluminum gallium arsenide (AlGaAs) doped at 10¹⁶ n-type particles/cm³ being 10 μm thick and in contact with the first layer 1330,
iii. a third layer is a p-type material, preferably gallium arsenide (GaAs) is doped with 10¹⁶ p-type particles/cm³ being 1 mm thick and in contact with the second layer,
and
b) a bottom cell 1500 attached to the top cell 1300 optimized to absorb incident energy in a second absorption spectrum which preferably does not substantially overlap the first absorption spectrum, the bottom cell 1500 having a quantum well region 1550 comprised of a plurality of pairs of layers, the pairs of layers having a selected material, sized and doped to create quantum wells having peak energy tuned to be about 1 eV, wherein the pairs of layers in the quantum well region 1550 comprise:
i. a gallium arsenide (GaAs) layer 1502, and
ii. a germanium (Ge) layer 1503.

In an alternative embodiment, the present invention may be embodied as a high-efficiency solar cell comprising:

a) a top cell 1300 optimized to absorb incident energy in a first absorption spectrum having:
i. a first layer 1330 being a highly doped n-type material aluminum gallium arsenide (AlGaAs) doped with 10¹⁸ n-type particles/cm³ being 0.5 μm thick,
ii. a second layer 1350 being a lightly doped n-type material, such as gallium arsenide (GaAs) doped with 10¹⁶ n-type particles/cm³ being 10 μm thick in contact with the first layer 1330,
iii. a third layer is a p-type layer, preferably germanium (Ge) doped with 10¹⁷ p-type particles/cm³ being 1.5 μm thick in contact with the second layer 1330;
and
b) a bottom cell 1500 attached to the top cell 1300 optimized to absorb incident energy in a second absorption spectrum which preferably does not substantially overlap the first absorption spectrum, the bottom cell 1500 having a quantum well region 1550 comprised of a plurality of pairs of layers, the pairs of layers having a selected material, sized and doped to create quantum wells having a peak energy tuned to be about 1 eV, wherein the pairs of layers in the quantum well region 1550 comprise:
i. a gallium arsenide (GaAs) layer 1502, and
ii. a germanium layer (Ge) 1503.

### BRIEF DESCRIPTION OF THE DRAWINGS

While the novel features of the invention are set forth with particularity in the appended claims, the invention, both as to organization and content, will be better understood and appreciated, along with other objects and features thereof, from the following detailed description taken in conjunction with the drawing, in which:

FIG. 1 shows a solar cell according to one embodiment of the present invention.

FIG. 2 is an enlarged view of the top cell 1300 of FIG. 1.

FIG. 3 shows a photo absorption spectrum for layers AlGaAs—GaAs—Ge superimposed on a 6000 K blackbody illumination spectrum.

FIG. 5 shows the power curve output for AlGaAs—GaAs—Ge model top cell.

FIG. 6 shows the current vs. voltage (I/V) characteristics of the cell for the AlGaAs—GaAs—Ge model top cell.

FIG. 7 shows is an enlarged view of the bottom cell 1500 of FIG. 1 and the lower layer 1350 of top cell 1300.

FIG. 8 shows an alternative embodiment of a high-efficiency solar cell according to the present invention.

FIG. 9 shows an implementation of a solar cell 8000 of FIG. 8.

### DETAILED DESCRIPTION OF A PREFERRED EMBODIMENT

### Theory

Multi-stack solar cells provide the advantage of several energy gaps that co-exist in the same device, where three (or perhaps more) solar cells are grown on top of each other. Multi-junction solar cell designs have been proposed by several groups, especially in the Ill-N-V regime (e.g. GalnNAs) where lattice matched semiconducting layers offer opportunities for complimentary energy gaps and thus higher absorption. This class of photovoltaic structures suffers from poor movement of electrons and ‘holes’ through a material, known as ‘carrier transport’.

Another drawback to most prior art multi-layer solar cell designs is that cells are typically chosen on efficiency with little consideration given to their transparency spectrum.

This causes a layer to be exposed to energy outside its main absorption band causing the energy to be converted to waste energy, such as heat.

The goal behind the stacked multiple solar cell design of the present invention is to a) position the materials having the largest energy gap (the energy required to release an electron) located near the top of the cell to absorb higher energy light in the upper layers, b) select materials which would allow larger portion of radiant energy to pass through the upper layers to the lower layers, c) allow lower energies to be absorbed in the lowest cell, and d) structure the materials to allow high electron mobility throughout the cells. Therefore, one would like to optimize these parameters.

The novel, multi-layer, high efficiency solar cell 1000 according to the present invention includes a combination of lattice-matched materials (semiconductors) for simultaneous photon absorption of different energy values. The advantage of such a device would be an inevitable increase of the carriers' population and hence an increase of the collection efficiency.

The use of double- or triple-layer solar cells with more than one material combination could lead to higher efficiency solar cells. Multilayered solar cells hold the answer to multiple photon absorption, and thus to higher collection efficiencies. Optimization involves using specific combinations of the number of layers, their relative sizes and their material compositions to create lattice-matched materials which can greatly affect the efficiency of the cell.

Solar cells receive radiant energy and either convert it to electricity, allow the radiant energy to transparently pass through the cell, or convert the radiant energy into wasted energy such as heat which increases recombination of electrons and ‘hole’, or causes relaxation of the electrons preventing them from being freed.

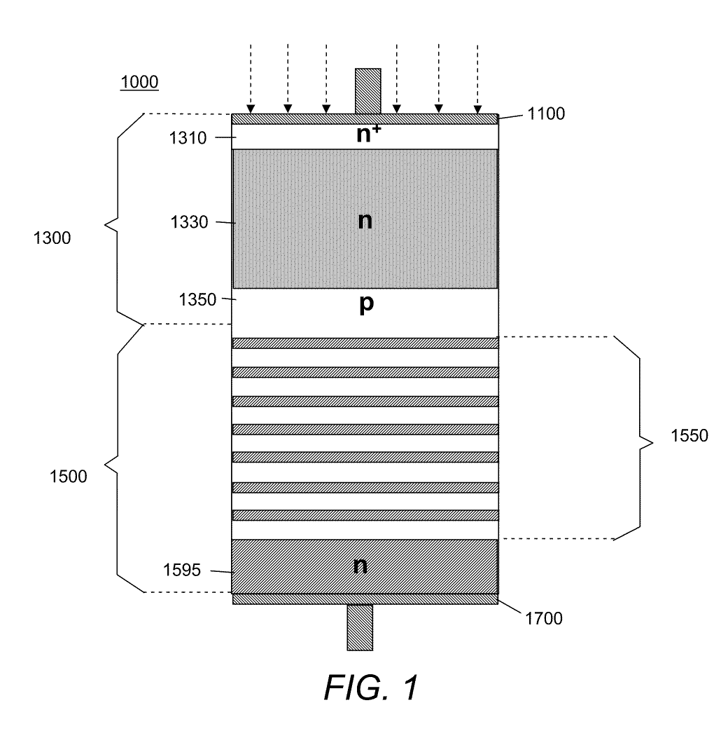

FIG. 1 shows a solar cell according to one embodiment of the present invention. This embodiment includes two cells which absorb energy in complementary energy bands:
(a) The top cell 1300 which is a dual junction triple layer solar cell composed of an n+ layer 1310, an n-type layer 1339 and a p-type layer 1350.
(b) The bottom cell 1500 is comprised of a layer 1510 then a superlattice quantum well region 1550 sandwiched between the p-type layer 1350 of the top cell 1300 and n-type 1595 of the bottom cell 1500.

Metal contact 1100 is in contact with the top cell 1300 with another metal contact 1700 in contact with bottom cell 1500.

The present invention is designed to absorb the high energy radiant energy in the higher frequencies in top cell 1300. The top cell 1300 is also designed to maximize transmission of radiant energy through it to the bottom cell 1500. Since the higher frequencies are absorbed by top cell 1300, the lower frequencies may be transmitted to the bottom cell 1500. Both the top and bottom cells are designed to complement each other in this way. Both the top and bottom cells, 1300, 1500 are also designed to minimize energy loss due to thermal effects and other means of wasted energy.

As radiant energy (light) impinges upon layer 1310, electrons are released and pass though the lightly doped n-type layer 1330 toward p-type layer 1350.

The top cell 1300 is designed to transmit lower energy light through it to bottom cell 1500. The radiant energy transmitted through layers 1310, 1330 and 1350 impacts upon the quantum well region 1550 designed to convert to electricity the lower energy radiant energy which are transmitted through the top cell 1300.

The bottom cell 1500 is designed to absorb radiant energy in the frequency range which the top cell transmits. This way, a combination of cells can effectively convert energy at frequencies from the visual to the near infrared regions into electricity.

The top cell 1300 and the bottom cell 1500 employ lattice-matched materials. Lattice matched materials have a similar spacing of molecules in the crystalline structures allowing electrons to pass from one material to the other adjacent material.

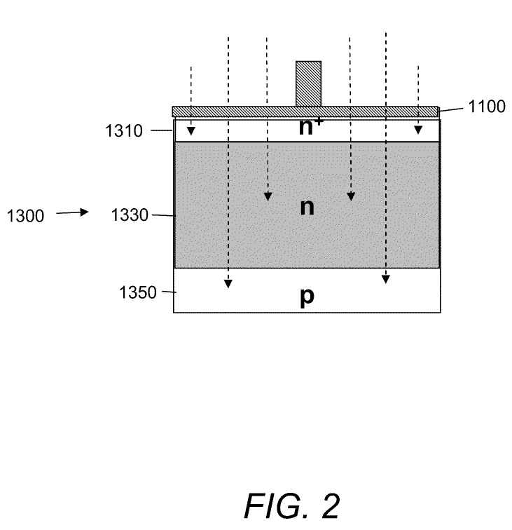

Top cell 1300 is described in more detail with reference to FIG. 2.

Since the transmission of radiant energy through the top cell 1300 is as critical as its absorption characteristics, the present invention optimizes the layering of bulk materials for both absorption and transmission. By sacrificing some of the gains that can be obtained by increased absorption we can significantly reduce the losses due to thermal and stimulated recombination effects in upper layers. Furthermore, this approach leads to the ability to place these layered materials over more exotic photovoltaics designed to take advantage of the transmitted spectrum. This alternative has advantages in that it has a significantly reduced loss in energy, such as thermal losses.

Two junction lattice-matched n+−n−p cell

To counter the carrier transport problem, the top cell 1300 employs three regions (n+−n−p), without the n-component, where lattice-matched layers are of basically three different band gaps in the short and the long wavelength range. The structure and carrier type selection is similar to p-i-n or n-i-p geometries, where long intrinsic (middle regions) provide long “depletion” regions where carriers can be swept rather fast.

By using a lightly doped central region an n+−n−p structure can take on an n-i-p character. The central region (acting as an intrinsic region) allows for higher carrier transport speeds.

Our overall design requires a top cell with specific transmission characteristics. Significant transmission of energy in the 1 eV range is required to provide an excitation energy appropriate for bottom cell 1500. The four lattice matched materials, listed along with their widest band gap, fall within our criteria are used for the layers of the top cell 1300. Aluminum Arsenide (AlAs) (2.3 eV) was chosen for layer 1310. Aluminum Gallium arsenide (AlGaAs) (1.8 eV) was used for layer 1330. Gallium Arsenide (GaAs) (1.4 eV) was chosen for 1350. Germanium (Ge) (0.64 eV) was chosen for layer 1595.

### Device

FIG. 2 is an enlarged view of the top cell 1300 of FIG. 1. Electron mobility may be examined here. This 12 micrometer, two-junction device has a thin (0.5 micrometer) AlGaAs layer 1310 of highly doped n-AlGaAs (10¹⁸ cm³).

The center layer 1330 is 10 micrometers thick, consists of lightly doped n-GaAs (10¹⁶ cm³).

The third layer 1350 is 1.5 micrometers thick, consists of p doped Ge.

The lightly doped thick central region gives this device an n-i-p character, while the device exploits the multi-junction advantage to provide superior mobility and achieve high short circuit currents.

There was extensive experimentation performed on the size and thickness of these layers and the materials used and the amount of doping to provide these results.

### Performance Estimate

In order to estimate maximum performance without the undue experimentation, a methodology was created.

As stated above, the radiant energy was modeled as a Plank's law black body radiator at 6000K.

Lorenz broadened absorption lines were used to calculate the maximum theoretical energy fraction available to these cells. This energy was determined using

$$\frac{\int I ( v ) hvA ( v ) d v}{\int I ( v ) hv d v} \qquad ( 1 )$$

with I(v) the fundamental equation for a Plank's Law black body radiator and

$$A ( v ) = \sum \frac{1}{1 + {( \frac{x - {x}_{0}}{γ} )}^{2}} \qquad ( 2 )$$

summed over all layers and normalized with γ=0.075 for the Lorenz broadened line width. The selection of γ is arbitrary, and was chosen to make the maximum theoretical energy fraction (MTEF) equal to the values we had calculated for the high efficiency cover cell (AlAs, AlGaAs, GaAs) previously reported.

### Modeling the AlGaAs—GaAs—Ge Dual Junction Solar Cell.

Modeling of the electrical characteristics of the cell followed standard solar cell analysis. The effect of doping level and layer thickness on carrier mobility, recombination, open circuit voltage, short circuit currents and maximal power output was used to find the optimum device configuration. Maximum efficiency was calculated using the relationship

$$η = \frac{{P}_{o}}{{P}_{i}} = \frac{{I}_{m} {V}_{m}}{{P}_{i}} \qquad ( 3 )$$

where both Im and Vm are the values found at the power maximum condition and Pi was the power incident on the cell from a 6000K black body radiator.

Setting the differential of power to voltage to 0 results in a maximum value.

$$\frac{\partial P}{\partial V} = 0 \qquad ( 4 )$$

Pi=Intensity/Cell Area=(110 mW/cm²)/1 cm²=100 mW

### Results

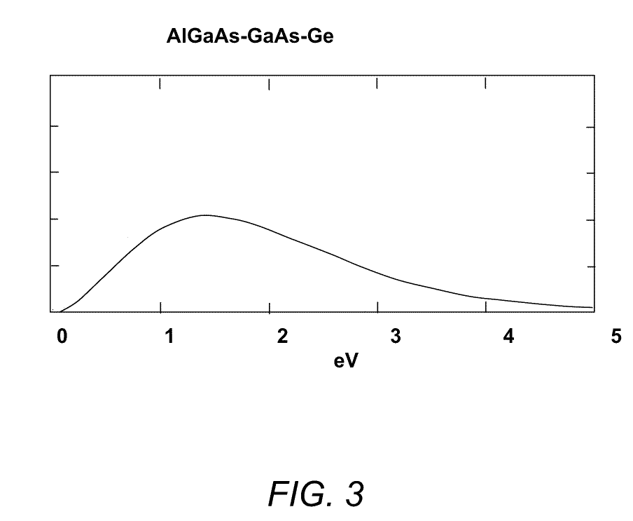

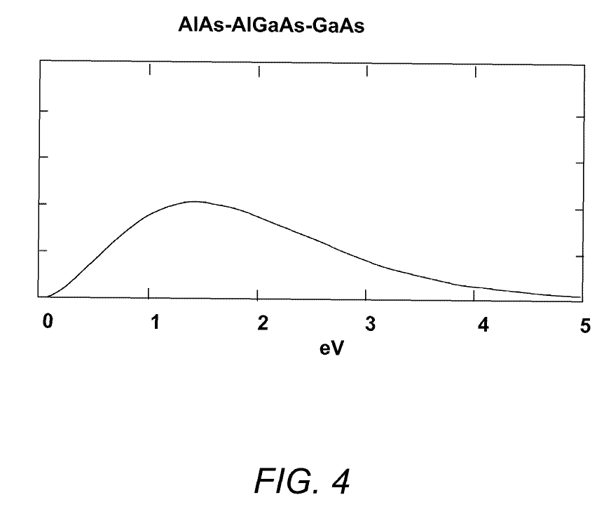

FIG. 3 shows Lorenz broadened photo absorption spectrum for layers AlGaAs—GaAs—Ge superimposed on a 6000K blackbody illumination spectrum. The MTEF for a three layer top cell of AlGaAs—GaAs—Ge was found to be 16%. The absorption lines for the top cell 1300 (shown as dashed lines) have a minimum around the 1 eV spectrum. These would be appropriate for use as upper layers of a multi layer solar cell if the lower layers will be absorbing light energy at approximately 1 eV.

FIG. 4 shows the Lorenz broadened photo absorptions lines for layers AlAs-AlGaAs-GaAs superimposed on a 6000K blackbody illumination spectrum. Here it can be seen that the absorption spectrum for the upper layers is now in the 1-3 eV range where the first peak is well above 1 eV.

These layers do not absorb light energy near the 1 eV range and allow them pass through to the bottom cell 1500, tuned to absorb radiant energy at 1 eV. This allows the bottom cell 1500 designed to absorb in the 1 eV range to absorb and convert this energy to electron flow, thereby resulting in a solar cell with increased efficiency.

Other lattice matched materials which are potential materials for a triple cell top cell 1300 are:

AlAs-AlGaAs-GaAs,
AlAs-AlGaAs-Ge,
AlAs-GaAs-Ge,
and
AlGaAs-GaAs-Ge.

An empirical method was determined to estimate the maximum efficiency of various materials and structures. This method calculates the percentage of incident energy that the cell should be capable of using, scaled to match the maximum efficiency we obtained in three layer (double junction) lattice matched photovotaics. The AlAs—AlGaAs—GaAs structure of FIG. 4 used as a top cell 1300 was previously determined by the present inventors to have an MTEF of 21%.

| | MTEF and Maximum |
|---|---|
| Cell Composition | Expected Efficiency |
| AlAs-AlGaAs-GaAs | 21% |
| AlAs-AlGaAs-Ge | 18% |
| AlAs-GaAs-Ge | 17% |
| AlGaAs-GaAs-Ge | 16% |

Results for four triple cell combinations are shown in the table above. Using the same analysis, the four-layer cell AlAs—AlGaAs—GaAs—Ge was determined to have a MTEF of 24%, so we can expect a four layer (three junction) top cell of that structure to yield a maximum efficiency of 24%.

It is apparent from FIG. 4 that all of cells mentioned meet the principal design criteria that they avoid the 1 eV energy region, the target energy gap of the bottom cell 1500.

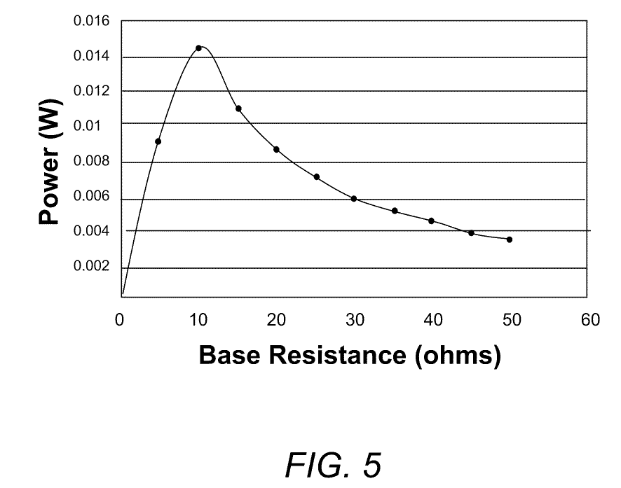

FIG. 5 shows the power curves for AlGaAs—GaAs—Ge model top cell.

A 14.5% improvement in cell efficiency was realized bringing the efficiency of the cell to 15%. This agrees well with our MTEF analysis (16%). This is 93% of the maximum expected efficiency of this device through this simple parameter optimization. Average photogeneration in the n+ region (AlGaAs) is found to be 10¹⁸ cm⁻³, in the mid region (GaAs) 10¹⁵ cm⁻³ and in p region (Ge) 1.5×10¹⁷ cm⁻³. (Only front surface recombination is taken into account (Sn=Sp=10³ cm/sec).)

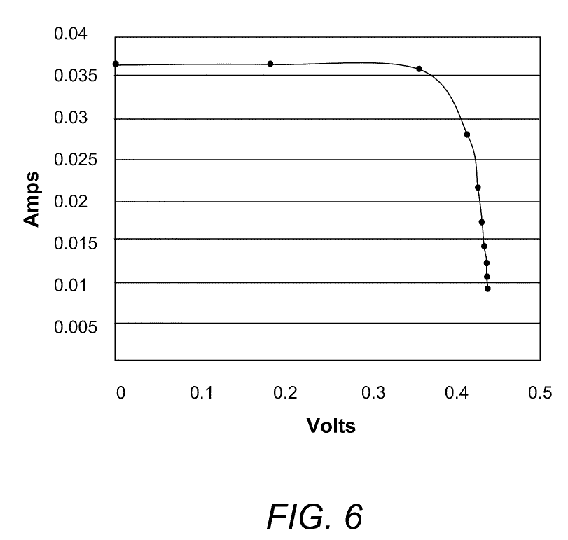

FIG. 6 shows the current vs. voltage (I/V) characteristics of the cell for the AlGaAs—GaAs—Ge model top cell.

When excited by a 100 mW/cm² 6000K black body source a 12 um thick cell with cross sectional area of 1 cm² is calculated to have an open circuit voltage of 0.39 V, a short circuit current of 0.47 A and a peak power of 14.7 mW.

This corresponds to an efficiency of approximately 15% for top cell 1300.

### Bottom Cell-Quantum Region

A quantum well is a potential well that confines particles, which were originally free to move in three dimensions, to two dimensions, forcing them to occupy a planar region. The effects of quantum confinement take place when the quantum well thickness becomes comparable at the de Broglie wavelength of the carriers (generally electrons and holes), leading to energy levels called “energy subbands”, i.e., the carriers can only have discrete specified energy values. Once an electron exceeds the maximum energy level of a quantum well, then the electron is freed allowing to move freely through the substrate.

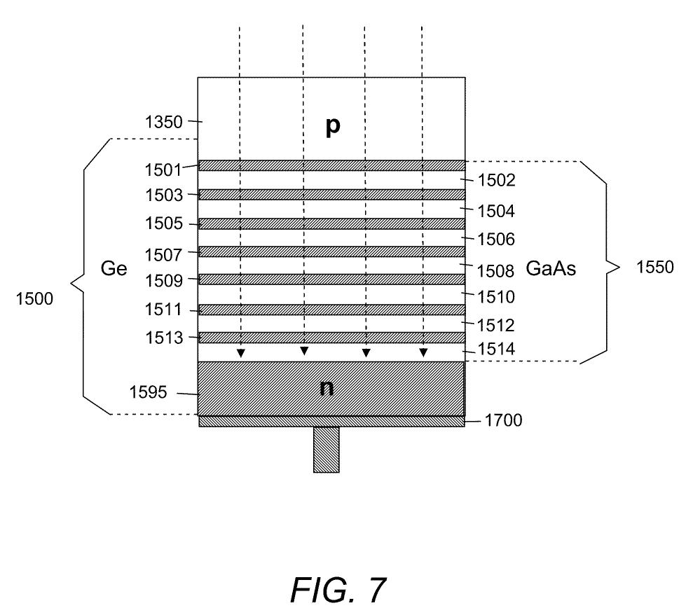

FIG. 7 shows the bottom cell 1500 and the lower layer 1350 of top cell 1300. The superlattice section 1550 is designed to be attached to the top cell 1300 and absorb radiant energy transmitted through top cell 1300. Bottom cell 1500 is optimized to absorb energy around the 1 eV.

The quantum region 1550 of the bottom cell 1500 is where quantum size effects occur. Quantum region 1550 is constructed from pairs of material layers which create quantum wells. In this embodiment, alternating thin germanium (Ge) layers 1501, 1503, 1505, 1507, 1509, 1511, 1513 are sandwiched by gallium arsenide (GaAs) layers 1502, 1504, 1506, 1508, 1510, 1512, 1514 to function as quantum wells tuned to absorb radiation at 1 eV. The thin germanium layers (20 nm) behave as quantum traps and confine electrons in a discrete set of energy levels (one or two at the most). Photo-excited carriers in this region are trapped in the quantum wells.

When a photon hits an electron in this quantum well, the electron is bounced up to the next discrete energy level. Once the electron's energy level exceeds the maximum energy of the well, the photo-electrons escape these traps and move to the conduction band. The electrons bounced out of the well are then allowed to drift in the substrate. In other words, the electron is moved from its valence band to its conduction band allowing it to be freed allowing it to drift as free current.

Once they are released to the conduction band and are free to flow, they must be forced to the conductor 1700. One such way is by the electrostatic attraction to the n-type layer 1595 and repulsion from the p-type layer 1350.

Another design which would pass the escaping electrons from the quantum wells to the conductor 1700 would be to construct the quantum wells with decreasing escape energies from the top of the cell to the conductor 1700 at the bottom.

Therefore, assume that layer pair 1504, 1505 has a quantum well energy of 0.8 eV, and quantum well layer pair 1506, 1507 has an energy of 0.7 eV, and quantum well layer pair 1508, 1509 has an energy of 0.6 eV. If a photon strikes layer pair 1506, 1508 and an electron is released and moves upward, it is trapped in layer pair 1504, 1505.

However, if the released electron moved downward, it has more energy than layer pair 1508, 1509 can contain and therefore layer pair 1508, 1509 cannot trap the electron.

The electron moves downward to the next layer pair 1510, 1511 having a lower energy than any layers above it. It also cannot trap the electron. Since the layer pairs are arranged with the lowest energies at the bottom with successively higher energies moving to the top, the electrons are only allowed to flow in one direction, down to the conductor 1700.

By using quantum wells 1550 we can tune the absorption and transmission characteristics of the bottom cell 1300 to fit the transmission characteristics of the top cell 1500. By adjusting the materials and parameters that characterize the absorption and photoelectric properties of the quantum well we can achieve very high conversion efficiencies.

In alternative embodiments of the invention, other known solar cells which absorb around the 1 eV energy range may be used as the bottom cell 1500.

### Estimated Efficiencies

Finally, a quick assay method to predict peak efficiencies is evaluated using this and other data from our laboratory.

Current modeling of the top cell 1300 has indicated top efficiency values in excess of 21% (power out vs. power in).

The preliminary calculations for the bottom cell 1500 indicate efficiency in excess of 25%.

### Advantages of the Present Design

Some advantages of the present design over other high-efficiency full-spectrum solar cells are:
(a) No excess tunnel junctions are needed to connect the top cell 1300 to the bottom cell 1500,
(b) The bottom cell 1500 being a superlattice region, includes germanium layers tuned to absorb photons having energies near 1 eV (or more, depending on the quantum well thickness),
(c) There is high mobility of carriers in both the top cell 1300 and the bottom cell 1500; the mobility of the bottom cell 1500 is a direct advantage over existing III-N-V high efficiency competing (nitrogen based) solar cell structures,
(d) Perfect lattice matching among the layers, and
(e) high carrier transport.

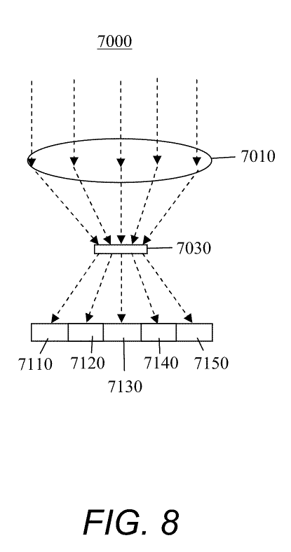

FIG. 8 shows an alternative embodiment of a high-efficiency solar cell 7000 according to the present invention.

A concentrator 7010 concentrates incident radiant energy on a refraction element 7030.

Refraction element 7030 splits the radiation into a spectrum which impinges on a solar cell array 7100.

Solar cell array 7100 includes cells 7110, 7120, 7130, 7140, 7150 each tuned to absorb a different frequency band.

The solar cells may be tuned to various frequency bands using the techniques described above.

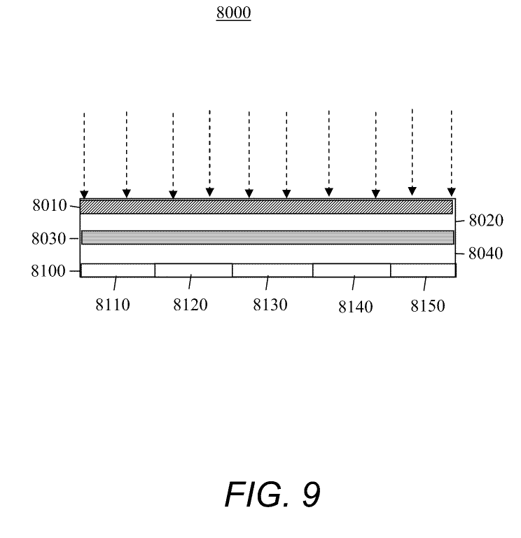

FIG. 9 shows an implementation of a solar cell 8000 of FIG. 8.

A ‘Fresnel-like’ layer 8010 and the high index of refraction layer 8020 are employed to concentrate and focus the radiation impinging on the device toward the center.

A diffraction grating 8030 is used as a refraction element to refract the concentrated radiation into its components frequencies.

Another high index of refraction layer 8040 directs the refracted radiant energy onto target 8100. Target 8100 is made of several target cells 8110, 8120, 8130, 8140, 8150 each tuned to convert the refracted energy impinging at their respective locations.

Much of the above is described in more detail in papers “Modeling of a New n+−n−p AlAs/AlGaAs/GaAs Solar Cell Δt 21% Collection Efficiency” by Argyrios C. Varonides, Robert A. Spalletta and Andrew W. Berger, “A Novel Full Spectrum High-Efficiency Multijunction Solar Cell” by Argyrios C. Varonides and “Modeling Issues For High Efficiency Top Cells in MultiLayer Voltaics” by Argyrios C. Varonides and Robert A. Spalletta all from the Physics and Engineering Department, The University of Scranton, Scranton, Pa. 18501, 570-941-6290. These papers are attached and all description and material are hereby incorporated by references as if set forth in their entirety in the body of the application.

The high index of refraction element 8040 is used to spatially fan out the refracted energy to impinge on a solar cell array 8100. The solar cell array have a plurality of solar cells 8110, 8120, 8130, 8140, 8150 each tuned to an absorption frequency band which is similar to the frequency band of the energy directed to it.

The structure of the design of this novel solar cell allows for this to be made as a flexible product. Many flexible materials, such as high refractive index plastics are known. Diffraction gratings may also be made as a flexible material.

While specific embodiments of the invention have been illustrated and described herein, it is realized that modifications and changes will occur to those skilled in the art. It is therefore to be understood that the appended claims are intended to cover all such modifications and changes as fall within the true spirit and scope of the invention.

1. A solar cell optimized to absorb incident energy in a first absorption spectrum and pass energy in a second absorption spectrum, the solar cell comprising:
a first layer being a highly doped n-type material,
a second layer being a lightly doped n-type material in contact with the first layer, and
a third layer is a p-type material in contact with the second layer, wherein the incident energy in the first absorption spectrum is absorbed by the layers of the solar cell and the energy of the second absorption spectrum passes through the layers of the solar cell.

2. The solar cell of claim 1, wherein the first, second and third layers are lattice matched.

3. The solar cell of claim 2, wherein the first layer is either aluminum arsenide (AlAs) or aluminum gallium arsenide (AlGaAs).

4. The solar cell of claim 3, wherein the second layer is selected from aluminum gallium arsenide (AlGaAs) or gallium arsenide (GaAs).

5. The solar cell of claim 4, wherein the third layer is either gallium arsenide (GaAs) or germanium (Ge).

6. The solar cell of claim 5, wherein the first layer is aluminum arsenide (AlAs) being 90 nm thick, doped at 10¹⁹ n-type particles/cm³, the second layer is aluminum gallium arsenide (AlGaAs) doped at 10¹⁶ n-type particles/cm³ being 10 μm thick, and the third layer is gallium arsenide (GaAs) is doped with 10¹⁶ p-type particles/cm³ being 1 μm thick.

7. The solar cell of claim 5, wherein the first layer is aluminum gallium arsenide (AlGaAs) doped with 10¹⁸ n-type particles/cm³ being 0.5 μm thick, the second layer is gallium arsenide (GaAs) doped with 10¹⁶ n-type particles/cm³ being 10 μm thick, and the third layer is germanium (Ge) doped with 10¹⁷ p-type particles/cm³ being 1.5 μm thick.

8. A photovoltaic system for producing electric current from light comprising a top cell and a bottom cell, the top cell optimized to absorb incident energy in a first absorption spectrum and pass energy in a second absorption spectrum through the top cell to the bottom cell, the bottom cell attached to the top cell and optimized to absorb incident energy in a second absorption spectrum which does not substantially overlap the first absorption spectrum.

9. The photovoltaic system of claim 8, the bottom cell comprising a quantum well region having a plurality of pairs of layers, the pairs of layers having a selected material, sized and doped to create quantum wells having peak energy tuned to be the energy in the second absorption spectrum.

10. The photovoltaic system of claim 9, wherein the pairs of layers of the quantum well region comprise:
i. a gallium arsenide (GaAs) layer, and
ii. a germanium (Ge) layer.

11. The system of claim 8, the top cell comprising:
a first layer being a highly doped n-type material,
a second layer being a lightly doped n-type material in contact with the first layer, and
a third layer is a p-type material in contact with the second layer, wherein the incident energy in the first absorption spectrum is absorbed by the layers of the solar cell and the energy of the second absorption spectrum passes through the layers of the solar cell; and
the bottom cell comprising:
a quantum well region having a plurality of pairs of layers, the pairs of layers having a selected material, sized and doped to create quantum wells having peak energy tuned to be the energy in the second absorption spectrum.

12. The photovoltaic system of claim 11, wherein the pairs of layers in the quantum well region comprise:
i. a gallium arsenide (GaAs) layer, and
ii. a germanium (Ge) layer.

13. A high efficiency solar cell for creating current from incident radiant energy, comprising:
a concentrator for concentrating the incident radiant energy into concentrated radiant energy,
a refraction element for receiving the concentrated radiant energy and splitting the radiant energy into a plurality of bands of radiant energy, each band of the plurality of bands having a frequency range and impinging on an area,
a plurality of band solar cells, each band solar cell disposed to receive one of the plurality of bands impinging on an area and also tuned to absorb the frequency range of the one of the plurality bands.

14. The solar cell of claim 13, wherein the concentrator comprises a layer of material having the properties of a Fresnel lens and a high index of refraction layer for concentrating and focusing the radiant energy.

15. The solar cell of claim 14, wherein the refraction element is a diffraction grating.

16. The solar cell of claim 15, further including a second high index of refraction layer for directing the radiant energy from the diffraction grating onto a plurality of targets, wherein each target coincides with the plurality of band solar cells.

17. The solar cell of claim 16, wherein the concentrator, refraction element, the plurality of band solar cells, and the second high index of refraction layer are layered together as a flexible product.
